(19) United States
(12) Patent Application Publication
(10) Pub. No.: US 2017/0359016 A1
(43) Pub. Date: Dec. 14, 2017

(54) SOLAR CELL SYSTEM INTEGRATED WITH WINDOW GLASS AND BLIND

(71) Applicant: Hyundai Motor Company, Seoul (KR)

(72) Inventors: Sol Kim, Suwon (KR); Sang Hak Kim, Seoul (KR); Mi Yeon Song, Seoul (KR)

(21) Appl. No.: 15/334,595

(22) Filed: Oct. 26, 2016

(30) Foreign Application Priority Data
Jun. 8, 2016 (KR) 10-2016-0070982

(51) Int. Cl. H02S 20/26; H01L 31/0747; H02S 40/32; H01G 9/20; H01L 31/0749; H01L 51/42; H02S 40/38; B60J 1/20; H02S 30/20

(52) U.S. Cl. CPC H02S 20/26; B60J 1/2013; H01L 31/0747; H02S 40/32; H02S 30/20; H01L 31/0749; H01L 51/4253; H02S 40/38; H01G 9/2059

(57) ABSTRACT

A solar cell system integrated with window glass and a blind is provided. The solar cell system includes high-power solar cell system that has two types of solar cells that are configured to absorb light with different wavelength bands from each other and are coupled to a window glass and a blind, respectively. The solar cell system includes a first solar cell that is coupled to a window glass and a second solar cell that is coupled to a blind and configured to absorb light different in wavelength band from light absorbed by the first solar cell. The band gap energy of the first solar cell is greater than the band gap energy of the second solar cell to maximize generation of electrical energy. Additionally, the second solar cell is coupled to the blind installed to open and close to increase power without degrading transmittance of the window glass.

### CROSS-REFERENCE TO RELATED APPLICATION

This application claims under 35 U.S.C. §119(a) the benefit of Korean Patent Application No. 10-2016-0070982 filed on Jun. 8, 2016, the entire contents of which are incorporated herein by reference.

### BACKGROUND

### (a) Technical Field

The present disclosure relates to a high-power solar cell system and more particularly, to a high-power solar cell system having two types of solar cells configured to absorb light with different wavelength bands from each other that are coupled to a window glass and a blind, respectively.

### (b) Background Art

Recently, research has been conducted to apply solar cells to buildings or window glasses of vehicles to improve energy efficiency, improve fuel economy, and reduce emission of carbon dioxide (CO₂). A developed apparatus of the related art includes a sunroof panel and a solar cell attached at one surface of the sunroof panel In particular, an increase in solar cell power is required to commercialize the solar cell system. Generally, solar cell power is increased by increasing a thickness of a light absorption layer that absorbs sunlight or by introducing a stacked tandem structure that includes two or more solar cells to absorb light with different wavelength bands from each other.

However, for the solar cells that are applied to buildings or window glasses of vehicles, when the thickness of the light absorption layer is increased or the tandem structure is introduced to increase solar cell power, the transmittance of the window glass deteriorates. Therefore, there is a need for development of a solar cell system which ensures transmittance of the window glass and provides high power when the solar cell system is applied to the window glass.

The above information disclosed in this section is merely for enhancement of understanding of the background of the invention and therefore it may contain information that does not form the prior art that is already known in this country to a person of ordinary skill in the art.

### SUMMARY

The present invention provides a solar cell system capable of ensuring both high power and transmittance of a window glass mounted in a building or a vehicle while mitigating the tradeoff relationship between the high power and the transmittance of the window glass. Another object of the present invention is to provide a solar cell system that maximizes power by using a combination of various solar cells.

In one aspect, the present invention provides an integrated solar cell system that may include a window glass and a blind configured to open and close and installed on the interior of the window glass to be spaced apart from the window glass at a predetermined distance. The integrated solar cell system may include a screen formed from of a flexible material and to obstruct light that enters the window glass, when a semi-transparent or transparent first solar cell may be coupled to the window glass and a flexible second solar cell is coupled to the screen of the blind.

In an exemplary embodiment, the window glass may be disposed in a building or a vehicle. In another exemplary embodiment, the blind may be a roll blind. The first solar cell and the second solar cell may be configured to absorb sunlight with different wavelength bands from each other. In some exemplary embodiments, band gap energy of the first solar cell may be greater than band gap energy of the second solar cell. The first solar cell may be selected from at least one of the group consisting of an organic solar cell, a perovskite solar cell, a dye-sensitized solar cell, an amorphous silicon solar cell, and a CIGS(Copper indium gallium selenide) thin film solar cell. In another exemplary embodiment, the second solar cell may be selected from at least one of the group consisting of an organic solar cell, a perovskite solar cell, an amorphous silicon solar cell, a crystalline silicon solar cell, and a CIGS thin film solar cell. The integrated solar cell system may further include a maximum power point tracking (MPPT) controller coupled to the first solar cell and the second solar cell and configured to operate the MPPT and a battery configured to store electrical energy generated by the first solar cell and the second solar cell.

The present invention having the aforementioned configurations may have the following effects. The solar cell system may provide high power without degrading transmittance of the window glass disposed in a building or a vehicle. Additionally, the solar cell system may maximize power by utilizing a combination of various solar cells. Further, according to the present invention, the solar cell system may minimize an increase in weight and may provide high power to considerably improve fuel economy and energy efficiency.

### BRIEF DESCRIPTION OF THE DRAWINGS

The above and other features of the present invention will now be described in detail with reference to exemplary embodiments thereof illustrated in the accompanying drawings which are given hereinbelow by way of illustration only, and thus are not limitative of the present invention, and wherein:

FIG. 1 is an exemplary reference view for explaining a band gap design of a first solar cell and a second solar cell according to an exemplary embodiment of the present invention;

FIG. 2 is an exemplary reference view for explaining the band gap design of the first solar cell and the second solar cell according to an exemplary embodiment of the present invention;

FIG. 3 is an exemplary view illustrating a solar cell system according to an exemplary embodiment of the present invention;

FIG. 4 is an exemplary view illustrating a solar cell system according to an exemplary embodiment of the present invention;

FIG. 5 is an exemplary view illustrating a solar cell system according to an exemplary embodiment of the present invention; and

FIG. 6 is an exemplary view for explaining an MPPT control unit and a battery of the solar cell system according to an exemplary embodiment of the present invention.

Reference numerals set forth in the Drawings include reference to the following elements as further discussed below:
10: window glass
20: blind
21: screen
22: roll bar
30: first solar cell
40: second solar cell

It should be understood that the appended drawings are not necessarily to scale, presenting a somewhat simplified representation of various exemplary features illustrative of the basic principles of the invention. The specific design features of the present invention as disclosed herein, including, for example, specific dimensions, orientations, locations, and shapes will be determined in part by the particular intended application and use environment. In the figures, reference numbers refer to the same or equivalent parts of the present invention throughout the several figures of the drawing.

### DETAILED DESCRIPTION

Hereinafter reference will now be made in detail to various exemplary embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

Hereinafter, the present invention will be described in detail through exemplary embodiments. The exemplary embodiments of the present invention may be modified to various forms without departing from the subject matter of the present invention. However, the scope of the present invention is not limited to the following exemplary embodiments. Descriptions of publicly known configurations or functions will be omitted so as to avoid unnecessarily obscuring the subject matter of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, in order to make the description of the present invention clear, unrelated parts are not shown and, the thicknesses of layers and regions are exaggerated for clarity. Further, when it is stated that a layer is “on” another layer or substrate, the layer may be directly on another layer or substrate or a third layer may be disposed therebetween.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Furthermore, control logic of the present invention may be embodied as non-transitory computer readable media on a computer readable medium containing executable program instructions executed by a processor, controller/control unit or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

An integrated solar cell system according to the present invention may include a window glass 10 and a blind 20 disposed on an interior of the window glass to be spaced apart from the window glass at a predetermined distance. A semi-transparent or transparent first solar cell may be coupled to the window glass and a flexible second solar cell may be coupled to the blind. The window glass may have a predetermined shape and size and may be disposed in a building or a vehicle. Further, the window glass may include a sunroof for a vehicle, a panoramic roof for a vehicle, a door window for a vehicle, or a window glass of a building, or the like.

The blind may be disposed on an interior of the window glass to be spaced apart from the window glass at a predetermined distance and may include a screen 21 to obstruct light that passes through the window glass. However, when the blind is installed to open and close, the screen may be configured to selectively perform the light shielding operation. In other words, the blind may be opened when lighting is required and may be closed when light shielding and power generation are required. The blind may be a roll blind but is not limited to a particular type of blind. Therefore, the blind may include the screen that may be formed of a flexible material, a roll bar 22 to provide a space in which the screen may be rolled in the form of a roll and a drive unit configured to operate the screen to a rolled up position or an extended position from the roll bar.

The first solar cell may be configured to absorb light in a particular wavelength band which enters the window glass and convert the light into electrical energy. The shape and size of the first solar cell are not limited, but the first solar cell may have a similar shape and size as the window glass or may be formed to cover an overall area of the window glass. The maximum amount of light entering through the window glass may be absorbed. The first solar cell, specifically, a light absorption layer of the first solar cell may be formed from a substance configured to absorb light in a wavelength band of visible light. In particular, for the first solar cell, a semi-transparent or transparent solar cell may be used. Accordingly, transmittance of the window glass may be prevented from being degraded by the first solar cell. Therefore, the first solar cell may be selected from at least one of the group that includes an organic solar cell, a perovskite solar cell, a dye-sensitized solar cell, an amorphous silicon solar cell, and a CIGS thin film solar cell.

The second solar cell may be configured to absorb light in a particular wavelength band which passes through the window glass and the first solar cell and to convert the light into electrical energy. The second solar cell may be coupled to the screen of the blind. The second solar cell may be sized to maximally cover an overall area of the screen. Accordingly, the maximum amount of electrical energy may be obtained when the screen is fully extended. The second solar cell may be formed from a flexible material. The blind may be configured to be installed to open or close. For example, when the blind is in a rolled position (e.g., a stored position), the second solar cell may be flexible to be wound around the roll bar together with the screen. Therefore, the second solar cell may be a solar cell (e.g., a film type solar cell).

The second solar cell may be electrically connected with the first solar cell and may connected in parallel or in series with the first solar cell. The second solar cell may include a light absorption layer formed of a substance configured to absorb light with different wavelength band from the light absorbed by the first solar cell. In particular, the second solar cell may be formed from a substance configured to absorb light in a wavelength band that may not be absorbed by the first solar cell. Therefore, electrical energy that may be obtained by the solar cell system may be maximized. In particular, the second solar cell may be an opaque solar cell or may be the transparent solar cell. Therefore, the second solar cell may selected from be at least one of the group consisting of an organic solar cell, a perovskite solar cell, an amorphous silicon solar cell, a crystalline silicon solar cell, and a CIGS thin film solar cell.

As described above, a combination of the first solar cell and the second solar cell may be configured as the solar cells that use different wavelength band of light for photoelectric conversion. However, the first solar cell and the second solar cell may be configured to absorb light with different wavelength bands from each other and band gap energy of the first solar cell may be greater than band gap energy of the second solar cell to improve efficiency of the integrated solar cell system.

The band gap energy may include band gap energy of a semiconductor used for the first solar cell and/or the second solar cell. The solar cell may be configured to absorb photons at a higher energy level as the band gap energy increases and the solar cell having high band gap energy may be configured to absorb light in a short wavelength band compared to a solar cell having low band gap energy. The solar cell may be configured to absorb photons at an energy level that is greater than the band gap energy of the solar cell and may be configured to generate power. In other words, when solar energy (hv₀) in a full spectrum enters the integrated solar cell system, all of the photons having energy greater than band gap energy (Eg₁) of the first solar cell may be absorbed by the first solar cell.

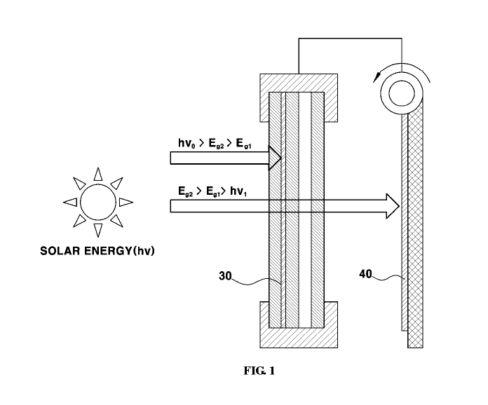

FIG. 1 illustrates the integrated solar cell system when band gap energy (Eg₂) of the second solar cell is greater than the band gap energy (Eg₁) of the first solar cell. Referring to FIG. 1, although the band gap energy Eg₂ of the second solar cell may be greater than the band gap energy Eg₁ of the first solar cell, the first solar cell 30 may be configured to absorb the photons at an energy level greater than the band gap energy Eg₁ of the first solar cell 30. In other words, the first solar cell 30 may be configured to absorb the photons to be absorbed by the second solar cell 40. Since an energy level of solar energy hv₁ that enters the second solar cell 40 may be less than the band gap energy Eg₂ of the second solar cell 40, the second solar cell 40 may not be capable of absorbing the solar energy hv₁. Since the solar cell may include a limitation in photoelectric conversion efficiency the efficiency of the integrated solar cell system may not be improved even though the first solar cell 30 and the second solar cell 40 are combined.

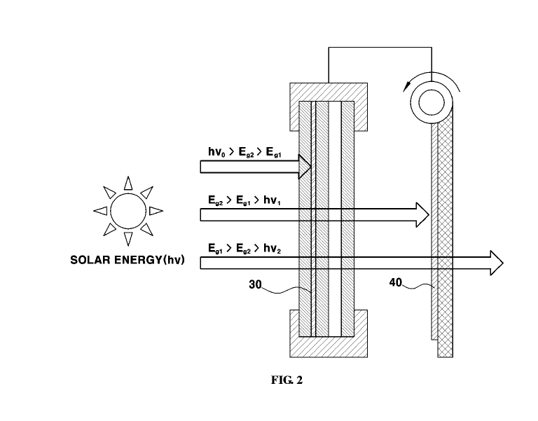

FIG. 2 illustrates the integrated solar cell system when the band gap energy Eg₁ of the first solar cell is greater than the band gap energy Eg₂ of the second solar cell. When the solar energy hv₀ passes through the first solar cell 30, the photon at an energy level greater than the band gap energy Eg₁ of the first solar cell 30 may be absorbed and the remaining solar energy hv₁ may enter the second solar cell 40. In other words, when the band gap energy Eg₂ of the second solar cell is less than the band gap energy Eg₁ of the first solar cell, the second solar cell may be configured to absorb the photon at an energy level less than the band gap energy Eg₁ of the first solar cell and greater than the band gap energy Eg₂ of the second solar cell. For example, both the first solar cell 30 and the second solar cell 40 may be configured to absorb solar energy at a predetermined level and generate power. Therefore, when the first solar cell and the second solar cell are combined, the band gap energy of the first solar cell may be greater than the band gap energy of the second solar cell. Accordingly, the photoelectric conversion efficiency may be improved. Further, the first solar cell and the second solar cell may be configured by a combination as shown in the following Table 1.

TABLE 1

| Combination | First Solar Cell | Second Solar Cell |
|---|---|---|
| 1 | Organic Solar Cell | Amorphous Silicon Solar Cell |
| 2 | Amorphous Silicon Solar | Crystalline Silicon Solar Cell |
| | Cell | |
| 3 | Organic Solar Cell | Perovskite Solar Cell |
| 4 | Perovskite Solar Cell | Crystalline Silicon Solar Cell |
| 5 | Organic Solar Cell | Organic Solar Cell |
| 6 | Dye-sensitized Solar Cell | Dye-sensitized Solar Cell |
| 7 | Dye-sensitized Solar Cell | CIGS Thin Film Solar Cell |

However, the combination is merely an example, the scope of the present invention is not limited thereto, and any combination is included in the exemplary embodiment of the present invention provided the wavelength bands of the light, that may be absorbed by the first solar cell and the second solar cell, respectively, are different from each other and the band gap energy of the first solar cell may be greater than the band gap energy of the second solar cell.

The solar cell system according to the present invention may include the first solar cell coupled to the window glass and the second solar cell coupled to the blind and may be configured to absorb light in a different wavelength band from light absorbed by the first solar cell. The electrical energy may be maximized and may be generated by the solar cell system. For example, the wavelength bands of the light absorbed by the first solar cell and the second solar cell may be adjusted and power of the solar cell system may be considerably improved.

In particular, the solar cell system according to the present invention may include the second solar cell attached to the blind (screen) and may be installed to open and close. Accordingly, power may be increased without degrading transmittance of the window glass.

In other words, the second solar cell may be attached to the blind to be spaced apart from the window glass at a predetermined distance and an increased thickness of the light absorption layer of the first solar cell or an introduction of the tandem structure to increase power of the solar cell system may not be required. Therefore, transmittance of the window glass may be provided when the blind is opened and visibility may be ensured. Further, when the blind is closed the power of the solar cell system may be increased through a synergy effect of the first solar cell and the second solar cell.

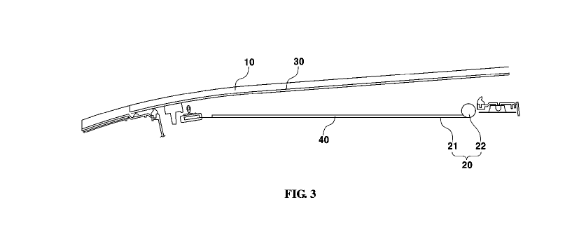

FIG. 3 illustrates an exemplary embodiment of the present invention that includes a solar cell system integrated with a sunroof and a roll blind for a vehicle. The solar cell system may be similarly applied to a panoramic roof for a vehicle by adjusting a structure. According to the exemplary embodiment of the present invention, the solar cell system may include a window glass, a blind (e.g., roll blind) disposed on the interior of the window glass, a first solar cell coupled to the window glass and a second solar cell coupled to the blind (e.g., screen).

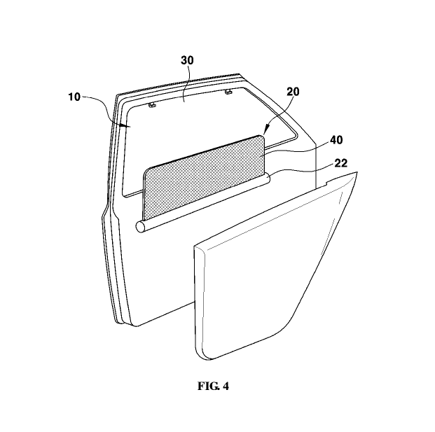

FIG. 4 illustrates an exemplary embodiment of the present invention that includes a solar cell system integrated with a door window and a door curtain (e.g., blind) for a vehicle. According to an exemplary embodiment of the present invention, the solar cell system may include a window glass (e.g., door window), a door curtain (e.g., roll blind) disposed on an interior of the window glass, a first solar cell coupled to the window glass and a second solar cell coupled to the door curtain.

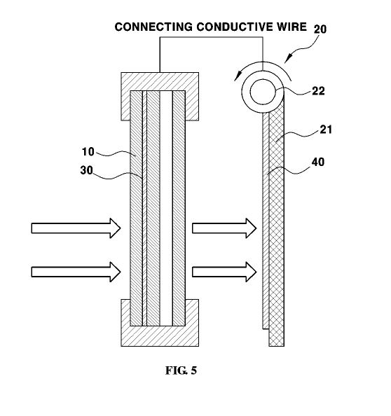

FIG. 5 illustrates an exemplary embodiment of the present invention that includes illustrates a solar cell system integrated with a window glass and a blind in a building. According to an exemplary embodiment of the present invention, the solar cell system may include a window glass, a blind (e.g., roll blind) disposed on the interior of the window glass, a first solar cell coupled to the window glass and a second solar cell coupled to the blind (e.g., screen).

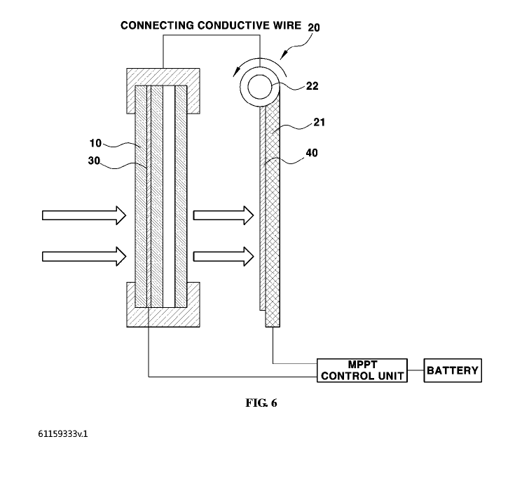

Referring to FIG. 6, the solar cell system according to the present invention may further include a maximum power point tracking (MPPT) controller which is connected with the first solar cell and the second solar cell and configured to operate by a controller the MPPT and a battery configured to store electrical energy generated by the first solar cell and the second solar cell. The first solar cell and the second solar cell may be different from each other in shape, size and the amount of light absorbed and as a result, the same power may not be obtained. Therefore, the maximum power point tracking may be performed by the MPPT controller. Accordingly, deterioration in efficiency caused by a difference in performance or power between the first solar cell and the second solar cell may be minimized.

The invention has been described in detail with reference to exemplary embodiments thereof. However, it will be appreciated by those skilled in the art that changes may be made in these exemplary embodiments without departing from the principles and spirit of the invention, the scope of which is defined in the appended claims and their equivalents.

1. An integrated solar cell system, comprising:
a window glass; and
a blind configured to open and close and installed on an interior of the window glass to be spaced apart from the window glass at a predetermined distance, and wherein the blind includes a screen formed from a flexible material and obstructs light entering the window glass,
wherein a semi-transparent or transparent first solar cell is coupled to the window glass, and a flexible second solar cell is coupled to the screen of the blind,
wherein the first solar cell and the second solar cell are configured to absorb sunlight with different wavelength bands from each other.

2. The integrated solar cell system of claim 1, wherein the window glass is disposed in a building or a vehicle.

3. The integrated solar cell system of claim 1, wherein the blind is a roll blind.

4. (canceled)

5. The integrated solar cell system of claim 1, wherein a band gap energy of the first solar cell is greater than a band gap energy of the second solar cell.

6. The integrated solar cell system of claim 1, wherein the first solar cell includes at least one selected from of the group consisting of an organic solar cell, a perovskite solar cell, a dye-sensitized solar cell, an amorphous silicon solar cell, and a CIGS thin film solar cell.

7. The integrated solar cell system of claim 1, wherein the second solar cell includes at least one selected from of the group consisting of an organic solar cell, a perovskite solar cell, an amorphous silicon solar cell, a crystalline silicon solar cell, and a CIGS thin film solar cell.

8. The integrated solar cell system of claim 1, further comprising:
a maximum power point tracking (MPPT) controller coupled with the first solar cell and the second solar cell, and configured to perform the MPPT; and
a battery configured to store electrical energy generated by the first solar cell and the second solar cell.
